(19) United States
(12) Patent Application Publication
(10) Pub. No.: US 2025/0062264 A1
(43) Pub. Date: Feb. 20, 2025

(54) SEMICONDUCTOR PACKAGE

(71) Applicant: Samsung Electronics Co., Ltd., Suwon-si (KR)

(72) Inventors: Jihyun LEE, Suwon-si (KR); Kang Joon LEE, Suwon-si (KR); Seokwon LEE, Suwon-si (KR)

(73) Assignee: Samsung Electronics Co., Ltd., Suwon-si (KR)

(21) Appl. No.: 18/623,202

(22) Filed: Apr. 1, 2024

(30) Foreign Application Priority Data
Aug. 18, 2023 (KR) 10-2023-0108318

(51) Int. Cl. H01L 23/00; H01L 23/498; H01L 23/60

(52) U.S. Cl. CPC H01L 24/16; H01L 23/49838; H01L 24/14; H01L 23/60; H01L 2224/14133; H01L 2224/16227; H01L 2924/15311

(57) ABSTRACT

A semiconductor package including a first structure, a second structure, and an interconnect structure between the first structure and the second structure. The interconnect structure includes a first region extending from a center of the interconnect structure to a first distance, and a second region outside the first region. The interconnect structure includes a plurality of first connection members in the first region and a plurality of second connection members in the second region. The plurality of first connection members are arranged in a staggered form, and the plurality of second connection members are arranged in rows.

### CROSS-REFERENCE TO RELATED APPLICATION

This application claims priority under 35 U.S.C. § 119 to Korean Patent Application No. 10-2023-0108318 filed in the Korean Intellectual Property Office on Aug. 18, 2023, the entire contents of which are incorporated herein by reference.

### BACKGROUND OF THE INVENTION

The present disclosure relates to semiconductor packages.

Surface mount technology (SMT) is a technology that attaches a semiconductor die to a connection pattern formed on the surface of a printed circuit board (PCB). When performing SMT, a solder ball is used as an intermediate medium to electrically connect the semiconductor die and the connection pattern on the PCB. As a technology for arranging such solder balls, ball grid array (BGA) technology, which connects a semiconductor die and a PCB by arranging solder balls in a grid, is well known.

BGA technology has the characteristic of arranging solder balls across the entire connection surface to increase (and/or maximize) the input and output signals required by the device. Therefore, using BGA technology can improve the power delivered to the device and reduce electrical resistance. On the contrary, when using BGA technology, warpage may occur in the semiconductor package when performing SMT. When warpage occurs in the semiconductor package, the solder balls arranged across the connection surface may collapse and come into contact with each other, causing a short between the solder balls.

Therefore, it is necessary to develop new semiconductor package technology that can solve these issues.

### SUMMARY

A semiconductor package according to some example embodiments of the inventive concepts includes a first structure, a second structure, and an interconnect structure between the first structure and the second structure. The interconnect structure includes a first region extending from a center of the interconnect structure to a first distance, a second region outside the first region, and a plurality of first connection members in the first region and a plurality of second connection members in the second region. The plurality of first connection members are arranged in a staggered form, and the plurality of second connection members are arranged in a row.

A semiconductor structure according to some example embodiments of the inventive concepts includes a die base, and a connection structure on a surface of the die base. The connection structure includes a first region extending from a center of the connection structure to a first distance, a second region outside the first region, an insulating member including a plurality of through openings, a plurality of first connection pads in the first region, and a plurality of second connection pads in the second region. The plurality of first connection pads and the plurality of second connection pads are within respective ones of the plurality of through openings. The plurality of first connection pads are arranged in a staggered form, and the plurality of second connection pads are arranged in a row.

A semiconductor package according to some example embodiments of the inventive concepts includes a substrate including a first die base, a plurality of first connection pads on an upper surface of the first die base, and a plurality of second connection pads on the upper surface of the first die base; a semiconductor structure including a second die base, a plurality of third connection pads on a lower surface of the second die base, and a plurality of fourth connection pads on the lower surface of the second die base; and an interconnect structure between the substrate and the semiconductor structure. The interconnect structure includes a first region extending from a center of the interconnect structure to a first distance, a second region outside the first region, and a plurality of first connection members in the first region and a plurality of second connection members in the second region. The plurality of first connection members are arranged in a staggered form, and the plurality of second connection members are arranged in a row.

A semiconductor package may be provided in which some of the connection members positioned in the first region of a connection surface between an upper structure and a lower structure are removed, and the connection members remaining in the first region are arranged in a staggered form. A semiconductor structure may be provided in which some of the connection pads positioned in the first region of a connection surface of the upper structure or the lower structure are removed, and the connection pads remaining in the first region are arranged in a staggered form.

With this, it is possible to increase the allowable value of warpage when performing surface mount technology (SMT), which means that even if the semiconductor package is warped, the connection members do not short each other.

Therefore, even if warpage of the semiconductor package occurs, when warpage occurs within the allowable value of increased warpage, a short between connection members will not occur, so the warpage allowable margin can be improved.

### BRIEF DESCRIPTION OF THE DRAWINGS

FIG. 1 is a cross-sectional view illustrating a semiconductor package according to some example embodiments of the inventive concepts.

FIG. 2 is a top plan view illustrating the arrangement of connection members in the semiconductor package of FIG. 1.

FIG. 3 is a cross-sectional view illustrating a case where bending occurs in a semiconductor package in the conventional art.

FIG. 4 is a cross-sectional view illustrating a case where warpage occurs in a semiconductor package according to some example embodiments of the inventive concepts.

FIG. 5 is a cross-sectional view illustrating a semiconductor package according to some other example embodiments of the inventive concepts.

FIG. 6 is a top plan view illustrating the arrangement of connection members in the semiconductor package of FIG. 5.

FIG. 7 is a cross-sectional view illustrating a semiconductor package according to some other example embodiments of the inventive concepts.

FIG. 8 is a top plan view illustrating the arrangement of connection members in the semiconductor package of FIG. 7.

FIG. 9 is a cross-sectional view illustrating a semiconductor package according to some other example embodiments of the inventive concepts.

FIG. 10 is a top plan view illustrating the arrangement of connection members in the semiconductor package of FIG. 9.

FIG. 11 is a cross-sectional view illustrating a semiconductor package according to some other example embodiments of the inventive concepts.

FIG. 12 is a top plan view illustrating the arrangement of connection members in the semiconductor package of FIG. 11.

FIG. 13 is a cross-sectional view illustrating a semiconductor package according to some other example embodiments of the inventive concepts.

FIG. 14 is a top plan view illustrating the arrangement of connection members in the semiconductor package of FIG. 13.

### DETAILED DESCRIPTION

Hereinafter, the inventive concepts will be described in detail with reference to the accompanying drawings, in which embodiments of the present disclosure are shown.

In the drawings, size and thickness of each constituent element are arbitrarily illustrated for better understanding and ease of description, and the following example embodiments are not limited thereto.

Throughout the specification, the term “connected” does not mean only “directly connected,” but may also mean “indirectly connected” with another element in between. Unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily positioned “on” or “above” in a direction opposite to gravity.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, a semiconductor package 10 of some example embodiments will be described with reference to the drawings.

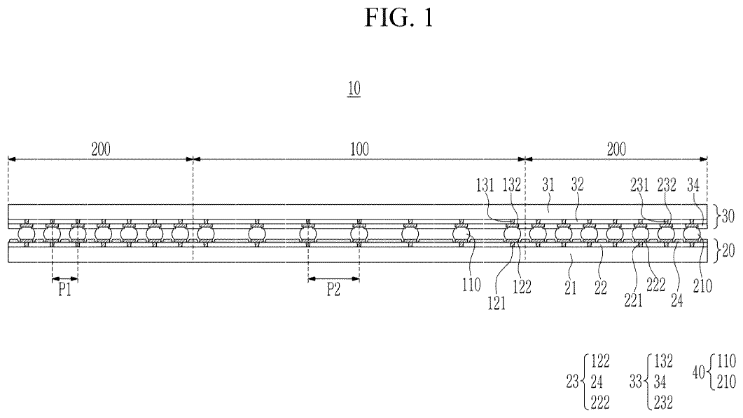

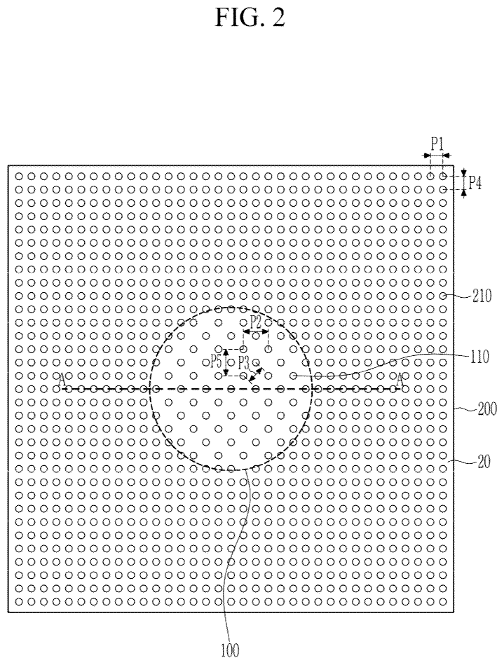

FIG. 1 is a cross-sectional view illustrating the semiconductor package 10 according to some example embodiments of the inventive concepts. FIG. 1 is a cross-sectional view of the top plan view of the semiconductor package 10 of FIG. 2 taken along line A-A. In FIG. 1, the area of a first region 100 of the semiconductor package 10 may be about 15% of the area of the entire region of the connection surface (the sum of the area of the first region 100 and the area of a second region 200). In some example embodiments, the area of the first region 100 of the semiconductor package 10 may be about 15% to about 30% of the area of the entire region of the connection surface (the sum of the area of the first region 100 and the area of the second region 200). In some example embodiments, the area of the first region 100 of the semiconductor package 10 may be about 5% to about 15% of the area of the entire region of the connection surface (the sum of the area of the first region 100 and the area of the second region 200).

Referring to FIG. 1, the semiconductor package 10 may include a lower structure 20, an upper structure 30, and an interconnect structure 40. The semiconductor package 10 may be divided into the first region 100 and the second region 200 based on region. The first region 100 may be defined as a region extending from the center of the semiconductor package 10 (the center of the interconnect structure 40) to a desired (and/or alternatively predetermined) distance, which may be characterized as a first distance. The second region 200 may be defined as a region outside the first region 100. The semiconductor package 10 may include a fine pitch ball grid array (FBGA) package.

The lower structure 20 may include a first die base 21, an insulating layer 22, first vias 121 of the first region 100, second vias 221 of the second region 200, and a first connection structure 23. In some example embodiments, the lower structure 20 may include a substrate. In some example embodiments, the lower structure 20 may include a printed circuit board (PCB). In some example embodiments, the lower structure 20 may include an interposer, a semiconductor chip, a three-dimensional integrated circuit (3DIC) structure, a bridge die, or a passive element.

The first die base 21 may include at least one of a circuit, a bridge, a semiconductor chip, a passive element, an active element, a wire, and a via.

The insulating layer 22 may protect and insulate the first via 121 of the first region 100 and the second via 221 of the second region 200. A first connection structure 23 may be disposed on the upper surface of the insulating layer 22. The first die base 21 may be disposed on the lower surface of the insulating layer 22. In some example embodiments, the insulating layer 22 may include FR-4. In some example embodiments, the insulating layer 22 may include at least one of epoxy and glass fiber. In some example embodiments, the insulating layer 22 may include an inorganic dielectric material such as silicon nitride and silicon oxide. In some example embodiments, the insulating layer 22 may include a photoimageable dielectric (PID). In some example embodiments, the insulating layer 22 may be formed by a CVD, ALD, or PECVD process.

The first via 121 of the first region 100 may be disposed between a wire (not shown) of the first die base 21 and a first connection pad 122 of the first region 100. The first via 121 of the first region 100 may electrically connect the first connection pad 122 of the first region 100 to the wire of the first die base 21. In some example embodiments, the first via 121 of the first region 100 may include at least one of copper, nickel, zinc, gold, silver, platinum, palladium, chromium, titanium, and alloys thereof. In some example embodiments, the first via 121 of the first region 100 may be formed by electroless plating or electrolytic plating. In some example embodiments, the first via 121 of the first region 100 may be formed by sputtering.

The second via 221 of the second region 200 may be disposed between the wire of the first die base 21 and a second connection pad 222 of the second region 200. The second via 221 of the second region 200 may electrically connect the second connection pad 222 of the second region 200 to the wire of the first die base 21. In some example embodiments, the second via 221 of the second region 200 may include at least one of copper, nickel, zinc, gold, silver, platinum, palladium, chromium, titanium, and alloys thereof. In some example embodiments, the second via 221 of the second region 200 may be formed by electroless plating or electrolytic plating. In some example embodiments, the second via 221 of the second region 200 may be formed by sputtering.

The first vias 121 of the first region 100 adjacent to each other among the first vias 121 of the first region 100 may have a second spacing P2. The second vias 221 of the second region 200 adjacent to each other among the second vias 221 of the second region 200 may have a first spacing P1. In some example embodiments, the second spacing P2 may be about twice the first spacing P1 of the second vias 221 of the second region 200 adjacent to each other among the second vias 221 of the second region 200.

In some example embodiments, the second spacing P2 may be about twice or more than the first spacing P1 of the second vias 221 of the second region 200 adjacent to each other among the second vias 221 of the second region 200. In some example embodiments, the second spacing P2 may be about more than twice and about less than or equal to four times the first spacing P1 of the second vias 221 of the second region 200 adjacent to each other among the second vias 221 of the second region 200. The first vias 121 of the first region 100 and the second vias 221 of the second region 200 may be formed simultaneously by a single process.

The first connection structure 23 may include the first connection pads 122 of the first region 100, the second connection pads 222 of the second region 200, and a first insulating member 24.

The first connection pad 122 of the first region 100 may be disposed between the first connection member 110 of the first region 100 and the first via 121 of the first region 100. The first connection pad 122 of the first region 100 may electrically connect the first connection member 110 of the first region 100 to the first via 121 of the first region 100. In some example embodiments, the first connection pad 122 of the first region 100 may include at least one of copper, nickel, zinc, gold, silver, platinum, palladium, chromium, titanium, and alloys thereof. In some example embodiments, the first connection pad 122 of the first region 100 may be formed by a sputtering process or by performing an electrolytic plating process after forming a seed metal layer.

The second connection pad 222 of the second region 200 may be disposed between the second connection member 210 of the second region 200 and the second via 221 of the second region 200. The second connection pad 222 of the second region 200 may electrically connect the second connection member 210 of the second region 200 to the second via 221 of the second region 200. In some example embodiments, the second connection pad 222 of the second region 200 may include at least one of copper, nickel, zinc, gold, silver, platinum, palladium, chromium, titanium, and alloys thereof. In some example embodiments, the second connection pad 222 of the second region 200 may be formed by a sputtering process or by performing an electrolytic plating process after forming a seed metal layer.

The first insulating member 24 may be disposed on the insulating layer 22. The first insulating member 24 may have a height from the surface of the insulating layer 22 higher (e.g., greater) than the height of the first connection pad 122 of the first region 100 from the surface of the insulating layer 22. The first insulating member 24 may have a height higher than the height of the second connection pad 222 of the second region 200. The first insulating member 24 may include a through opening for soldering. The first connection pad 122 of the first region 100 and the second connection pad 222 of the second region 200 may be disposed within the through opening of the first insulating member 24. The first insulating member 24 may limit and/or prevent the first connection members 110 of the first region 100 from being shorted to each other and the second connection members 210 of the second region 200 from being shorted to each other. In some example embodiments, the first insulating member 24 may include solder resist. In some example embodiments, the first insulating member 24 may be formed by performing a coating, exposure, development, and curing process.

The first connection pads 122 of the first region 100 adjacent to each other among the first connection pads 122 of the first region 100 may have the second spacing P2. The second connection pads 222 of the second region 200 adjacent to each other among the second connection pads 222 of the second region 200 may have the first spacing P1. In some example embodiments, the second spacing P2 may be about twice the first spacing P1 of the second connection pads 222 of the second region 200 adjacent to each other among the second connection pads 222 of the second region 200. In some example embodiments, the second spacing P2 may be about twice or more than the first spacing P1 of the second connection pads 222 of the second region 200 adjacent to each other among the second connection pads 222 of the second region 200. In some example embodiments, the second spacing P2 may be about more than twice and about less than or equal to four times the first spacing P1 of the second connection pads 222 of the second region 200 adjacent to each other among the second connection pads 222 of the second region 200. The first connection pads 122 of the first region 100 and the second connection pads 222 of the second region 200 may be formed simultaneously by a single process.

The upper structure 30 may include a second die base 31, an insulating layer 32, third vias 131 of the first region 100, fourth vias 231 of the second region 200, and a second connection structure 33. In some example embodiments, the upper structure 30 may include an interposer, a semiconductor chip, a three-dimensional integrated circuit (3DIC) structure, a bridge die, or a passive element. In some example embodiments, the upper structure 30 may include a system on a chip (SoC).

The second die base 31 may include at least one of a circuit, a bridge, a semiconductor chip, a passive element, an active element, a wire, and a via. In some example embodiments, the second die base 31 may include at least one of a neural network processing unit (NPU), a central processing unit (CPU), and a graphics processing unit (GPU). In some example embodiments, the second die base 31 may include at least one of a communication chip and a sensor.

The insulating layer 32 may protect and insulate the third via 131 of the first region 100 and the fourth via 231 of the second region 200. The second die base 31 may be disposed on the upper surface of the insulating layer 32. The second connection structure 33 may be disposed on the lower surface of the insulating layer 32. In some example embodiments, the insulating layer 32 may include FR-4. In some example embodiments, the insulating layer 32 may include at least one of epoxy and glass fiber. In some example embodiments, the insulating layer 32 may include an inorganic dielectric material, such as silicon nitride and silicon oxide. In some example embodiments, the insulating layer 32 may include a photoimageable insulator (PID). In some example embodiments, the insulating layer 32 may be formed by a CVD, ALD, or PECVD process.

The third via 131 of the first region 100 may be disposed between the wire (not shown) of the second die base 31 and the third connection pad 132 of the first region 100. The third via 131 of the first region 100 may electrically connect the third connection pad 132 of the first region 100 to the wire of the second die base 31. In some example embodiments, the third via 131 of the first region 100 may include at least one of copper, nickel, zinc, gold, silver, platinum, palladium, chromium, titanium, and alloys thereof. In some example embodiments, the third via 131 of the first region 100 may be formed by electroless plating or electrolytic plating. In some example embodiments, the third via 131 of the first region 100 may be formed by sputtering.

The fourth via 231 of the second region 200 may be disposed between the wire of the second die base 31 and a fourth connection pad 232 of the second region 200. The fourth via 231 of the second region 200 may electrically connect the fourth connection pad 232 of the second region 200 to the wire of the second die base 31. In some example embodiments, the fourth via 231 of the second region 200 may include at least one of copper, nickel, zinc, gold, silver, platinum, palladium, chromium, titanium, and alloys thereof. In some example embodiments, the fourth via 231 of the second region 200 may be formed by electroless plating or electrolytic plating. In some example embodiments, the fourth via 231 of the second region 200 may be formed by sputtering.

The third vias 131 of the first region 100 adjacent to each other among the third vias 131 of the first region 100 may be disposed to have the second spacing P2. The fourth vias 231 of the second region 200 adjacent to each other among the fourth vias 231 of the second region 200 may be disposed to have the first spacing P1. In some example embodiments, the second spacing P2 may be about twice the first spacing P1 of the fourth vias 231 of the second region 200 adjacent to each other among the fourth vias 231 of the second region 200. In some example embodiments, the second spacing P2 may be about twice or more than the first spacing P1 of the fourth vias 231 of the second region 200 adjacent to each other among the fourth vias 231 of the second region 200. In some example embodiments, the second spacing P2 may be about more than twice and about less than or equal to four times the first spacing P1 of the fourth vias 231 of the second region 200 adjacent to each other among the fourth vias 231 of the second region 200. The first vias 121 of the first region 100 and the fourth vias 231 of the second region 200 may be formed simultaneously by a single process.

The second connection structure 33 may include the third connection pads 132 of the first region 100, the fourth connection pads 232 of the second region 200, and a second insulating member 34.

The third connection pad 132 of the first region 100 may be disposed between the first connection member 110 of the first region 100 and the third via 131 of the first region 100. The third connection pad 132 of the first region 100 may electrically connect the third via 131 of the first region 100 to the first connection member 110 of the first region 100. In some example embodiments, the third connection pad 132 of the first region 100 may include at least one of copper, nickel, zinc, gold, silver, platinum, palladium, chromium, titanium, and alloys thereof. In some example embodiments, the third connection pad 132 of the first region 100 may be formed by a sputtering process or by performing an electrolytic plating process after forming a seed metal layer.

The fourth connection pad 232 of the second region 200 may be disposed between the second connection member 210 of the second region 200 and the fourth via 231 of the second region 200. The fourth connection pad 232 of the second region 200 may electrically connect the fourth via 231 of the second region 200 to the second connection member 210 of the second region 200. In some example embodiments, the fourth connection pad 232 of the second region 200 may include at least one of copper, nickel, zinc, gold, silver, platinum, palladium, chromium, titanium, and alloys thereof. In some example embodiments, the fourth connection pad 232 of the second region 200 may be formed by a sputtering process or by performing an electrolytic plating process after forming a seed metal layer.

The second insulating member 34 may be disposed below the insulating layer 32. The second insulating member 34 may have a height from the surface of the insulating layer 132 higher (e.g., greater) than the height of the third connection pad 132 of the first region 100 from the surface of the insulating layer 132. The second insulating member 34 may have a height higher than the height of the fourth connection pad 232 of the second region 200. The second insulating member 34 may include a through opening for soldering. The third connection pad 132 of the first region 100 and the fourth connection pad 232 of the second region 200 may be disposed within the through opening of the second insulating member 34. The second insulating member 34 may limit and/or prevent the first connection members 110 of the first region 100 from being shorted to each other and the second connection members 210 of the second region 200 from being shorted to each other. The second insulating member 34 may be in contact with the third connection pad 132 of the first region 100. The second insulating member 34 may be in contact with the fourth connection pad 232 of the second region 200. In some example embodiments, the second insulating member 34 may include solder resist. In some example embodiments, the second insulating member 34 may be formed by performing a coating, exposure, developing, and curing process.

The third connection pads 132 of the first region 100 adjacent to each other among the third connection pads 132 of the first region 100 may have the second spacing P2. The fourth connection pads 232 of the second region 200 adjacent to each other among the fourth connection pads 232 of the second region 200 may have the first spacing P1. In some example embodiments, the second spacing P2 may be about twice the first spacing P1 of the fourth connection pads 232 of the second region 200 adjacent to each other among the fourth connection pads 232 of the second region 200. In some example embodiments, the second spacing P2 may be about twice or more than the first spacing P1 of the fourth connection pads 232 of the second region 200 adjacent to each other among the fourth connection pads 232 of the second region 200. In some example embodiments, the second spacing P2 may be about more than twice and about less than or equal to four times the first spacing P1 of the fourth connection pads 232 of the second region 200 adjacent to each other among the fourth connection pads 232 of the second region 200. The third connection pads 132 of the first region 100 and the fourth connection pads 232 of the second region 200 may be formed simultaneously by a single process.

The interconnect structure 40 may include first connection members 110 of the first region 100 and second connection members 210 of the second region 200.

The first connection member 110 of the first region 100 may be disposed between the first connection pad 122 and the third connection pad 132. The first connection member 110 of the first region 100 may electrically connect the third connection pad 132 to the first connection pad 122. In some example embodiments, the first connection member 110 of the first region 100 may include solder balls or bumps. In some example embodiments, the first connection member 110 of the first region 100 may include at least one of tin, silver, lead, nickel, copper, or an alloy thereof. In some example embodiments, the first connection member 110 of the first region 100 may include SAC (Sn, Ag, and Cu).

The second connection member 210 of the second region 200 may be disposed between the second connection pad 222 and the fourth connection pad 232. The second connection member 210 of the second region 200 may electrically connect the fourth connection pad 232 to the second connection pad 222. In some example embodiments, the second connection member 210 of the second region 200 may include solder balls or bumps. In some example embodiments, the second connection member 210 of the second region 200 may include at least one of tin, silver, lead, nickel, copper, or an alloy thereof. In some example embodiments, the second connection member 210 of the second region 200 may include SAC (Sn, Ag, and Cu).

The first connection members 110 of the first region 100 adjacent to each other among the first connection members 110 of the first region 100 may have the second spacing P2. The second connection members 210 of the second region 200 adjacent to each other among the second connection members 210 of the second region 200 may have the first spacing P1. In some example embodiments, the second spacing P2 may be about twice the first spacing P1 of the second connection members 210 of the second region 200 adjacent to each other among the second connection members 210 of the second region 200. In some example embodiments, the second spacing P2 may be about twice or more than the first spacing P1 of the second connection members 210 of the second region 200 adjacent to each other among the second connection members 210 of the second region 200. In some example embodiments, the second spacing P2 may be about more than twice and about less than or equal to four times the first spacing P1 of the second connection members 210 of the second region 200 adjacent to each other among the second connection members 210 of the second region 200. The first connection members 110 of the first region 100 and the second connection members 210 of the second region 200 may be formed simultaneously by a single process.

FIG. 2 is a top plan view illustrating the arrangement of the first connection members 110 of the first region 100 and the second connection members 210 of the second region 200 in the semiconductor package 10 of FIG. 1. FIG. 2 is a top plan view illustrating the semiconductor package 10 of FIG. 1, with the upper structure 30 and the first insulating member 24 removed.

Referring to FIG. 2, the semiconductor package 10 may include the first region 100 and the second region 200. In some example embodiments, the first region 100 may include a circular shape. The first region 100 may have the center of the semiconductor package 10 (the center of the interconnect structure 40) as its center. In some example embodiments, the area of the first region 100 of the semiconductor package 10 may be about 15% of the area A of the entire region (the sum of the area of the first region 100 and the area of a second region 200) of the connection surface (the interconnect structure). In some example embodiments, the area of the first region 100 of the semiconductor package 10 may be larger or smaller than about 15% of the area A of the entire region of the connection surface. The first region 100 may have a radius extending from the center of the semiconductor package 10 (the center of the interconnect structure 40) to a desired (and/or alternatively predetermined) distance, which may be characterized as a first distance. In some example embodiments, the desired (and/or alternatively predetermined) distance of the first region 100 may be about

$$\sqrt{\frac{0.15 \times A}{π}} .$$

In some example embodiments, the desired (and/or alternatively predetermined) distance of the first region 100 may be greater or less than about

$$\sqrt{\frac{0.15 \times A}{π}} .$$

The second region 200 may be defined as a region outside the first region 100.

In the first region 100, the first connection members 110 may be arranged in a staggered form. The first connection members 110 adjacent to each other among the first connection members 110 in the first region 100 may be arranged with the second spacing P2 in a first horizontal direction (direction parallel to line A-A). A fifth spacing P5 in a third horizontal direction (direction orthogonal to line A-A) of the first connection members 110 adjacent to each other among the first connection members 110 in the first region 100 may be the same as the second spacing P2 in the first horizontal direction (direction parallel to the line A-A) of the first connection members 110 adjacent to each other among the first connection members 110 in the first region 100. The staggered form is an optimized form that allows for a wide arrangement of the second spacing P2 between the first connection members 110 adjacent to each other among the first connection members 110 in the first region 100, while still allowing for the necessary amount of input/output signals to be transmitted and received for the electrical connection between the lower structure 20 and the upper structure 30.

In the second region 200, the second connection members 210 may be arranged in a row. The second connection members 210 adjacent to each other among the second connection members 210 in the second region 200 may be arranged with the first spacing P1 in the first horizontal direction (direction parallel to line A-A). A fourth spacing P4 in the third horizontal direction (direction orthogonal to line A-A) of the second connection members 210 adjacent to each other among the second connection members 210 in the second region 200 may be the same as the first spacing P1 in the first horizontal direction (direction parallel to the line A-A) of the second connection members 210 adjacent to each other among the second connection members 210 in the second region 200.

The second spacing P2 in the first horizontal direction of the first connection members 110 of the first region 100 may be about twice the first spacing P1 in the first horizontal direction of the second connection members 210 of the second region 200. The second spacing P2 in the first horizontal direction of the first connection members 110 of the first region 100 may be greater than about twice the first spacing P1 in the first horizontal direction of the second connection members 210 of the second region 200. The third spacing P3 (in the second horizontal direction) between the first connection members 110 at the closest distance among the first connection members 110 of the first region 100 may be about √2 times the first spacing P1 in the first horizontal direction of the second connection members 210 of the second region 200. The third spacing P3 (in the second horizontal direction) between the first connection members 110 at the closest distance among the first connection members 110 of the first region 100 may be greater than about √2 the first spacing P1 in the horizontal or vertical direction of the second connection members 210 of the second region 200.

In the second region 200, the second connection members 210 are disposed as close to each other as possible, thereby allowing the semiconductor package 10 to have the maximum disposition density of the second connection members 210 in the second region 200. Accordingly, it is possible to transmit and receive the maximum amount of input/output signals required for electrical connection with the upper structure 30 by the second connection members 210 in the second region 200. In some example embodiments, the second connection members 210 in the second region 200 may be electrically connected to a high-performance circuit. In some example embodiments, in the second region 200, the second connection members 210 may be electrically connected to the lower structure 20 and the upper structure 30 including at least one of a NPU, a CPU and a GPU. Therefore, according to some example embodiments, it is possible to improve power transmitted to a high-performance circuit such as a NPU, a CPU, or a GPU by the second connection members 210 in the second region 200 and reduce electrical resistance.

In order to increase the allowable value of warpage of the semiconductor package 10, the second spacing P2 in the first horizontal direction of the first connection members 110 of the first region 100 may be about twice the first spacing P1 in the first horizontal direction of the second connection members 210 of the second region 200. Therefore, the first connection members 110 of the first region 100 may be connected to a device that consumes less power. In some example embodiments, the first connection members 110 of the first region 100 may be electrically connected to at least one of a communication chip and a sensor.

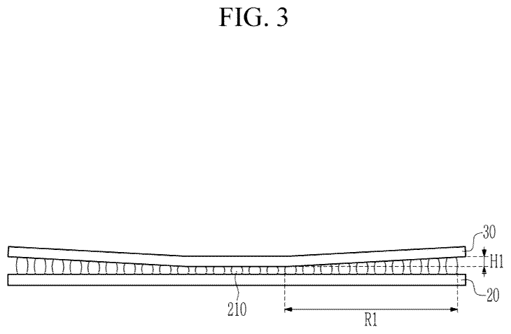

FIG. 3 is a cross-sectional view illustrating an example where bending occurs in a semiconductor package in the conventional art.

Referring to FIG. 3, the second connection members 210 may be disposed with maximum disposition density between the lower structure 20 and the upper structure 30. In the structure of FIG. 3, when warpage occurs in the semiconductor package and the second connection members 210 begin to be shorted to each other, the region where the short occurs between the second connection members 210 is marked as R1, and the height of the section where warpage must be considered because a short occurs is marked as H1. Therefore, in the conventional art, when warpage occurs in the semiconductor package, the sections in which a short between the second connection members 210 must be considered are R1 and H1.

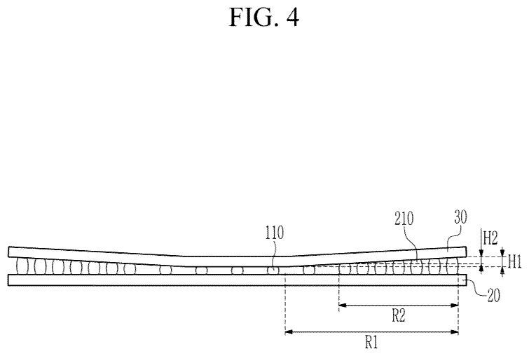

FIG. 4 is a cross-sectional view illustrating a case where warpage occurs in the semiconductor package 10 according to some example embodiments of the inventive concepts.

Referring to FIG. 4, the first connection members 110 in the first region 100 may have the second spacing P2 and a short does not occur in the first region 100. Referring to FIG. 1, in the semiconductor package 10, the second spacing P2 between the first connection members 110 in the first region 100 may be about twice the first spacing P1 between the second connection members 210 in the second region 200. Therefore, even if warpage occurs in the semiconductor package 10, the first connection members 110 in the first region 100 may not be shorted to each other, and the second connection members 210 in the second region 200 may be shorted to each other. Since a short circuit does not occur in the region where the first connection members 110 are disposed, when warpage occurs in the semiconductor package 10 and the second connection members 210 begin to short, the region where a short occurs between the second members 210 is R2, where the second connection members 210 are disposed, and the height of the section where warpage must be considered because the short occurs is H2.

According to some example embodiments of the inventive concepts, the region R2 where a short occurs between the second connection members 210 is significantly reduced compared to the region R1 where a short occurs between the second connection members 210 of the conventional art, and the height H2 where warpage must be considered to limit and/or prevent a short between the second connection members 210 is significantly reduced compared to the height H1 where warpage must be considered to limit and/or prevent a short between the second connection members 210 of the conventional art. Accordingly, the allowable margin for warpage increases.

As a result of testing, in FIGS. 1 and 2, where the area of the first region 100 of the semiconductor package 10 becomes about 15% of the area of the entire region (the sum of the area of the first region 100 and the area of the second region 200) of the connection surface (the interconnect structure), the allowable value of warpage is increased by about 8 μm compared to the allowable value of warpage based on the conventional art.

With this, the allowable value of warpage of the semiconductor package increases, so when performing SMT, the warpage of the semiconductor package may be adjusted within the allowable value of warpage to limit and/or prevent a short from occurring between the second connection members 210.

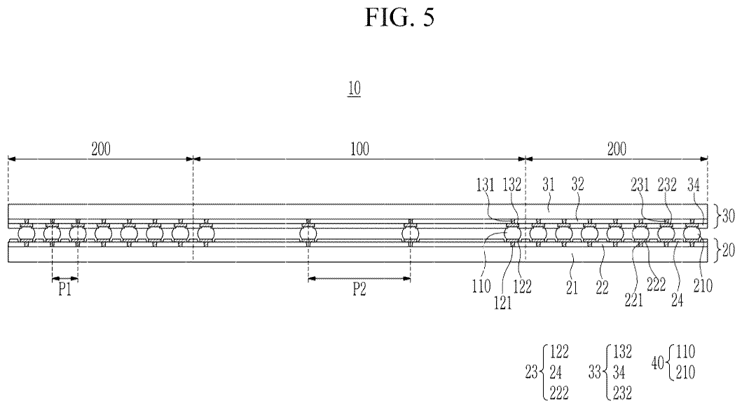

FIG. 5 is a cross-sectional view illustrating the semiconductor package 10 according to some other example embodiments of the inventive concepts.

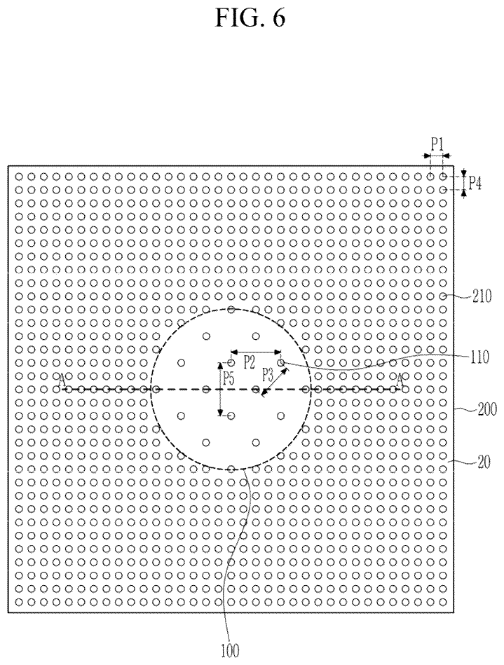

FIG. 5 is a cross-sectional view of the top plan view of the semiconductor package 10 of FIG. 6 taken along line A-A. In FIG. 5, the area of a first region 100 of the semiconductor package 10 may be about 15% of the area of the entire region of the connection surface (the sum of the area of the first region 100 and the area of a second region 200). In some example embodiments, the area of the first region 100 of the semiconductor package 10 may be about 15% to about 30% of the area of the entire region of the connection surface (the sum of the area of the first region 100 and the area of the second region 200). In some example embodiments, the area of the first region 100 of the semiconductor package 10 may be about 5% to about 15% of the area of the entire region of the connection surface (the sum of the area of the first region 100 and the area of the second region 200).

Referring to FIG. 5, the first vias 121 of the first region 100 adjacent to each other among the first vias 121 of the first region 100, the first connection pads 122 of the first region 100 adjacent to each other among the first connection pads 122 of the first region 100, the first connection members 110 of the first region 100 adjacent to each other among the first connection members 110 of the first region 100, the third connection pads 132 of the first region 100 adjacent to each other among the third connection pads 132 of the first region 100, and the third vias 131 of the first region 100 adjacent to each other among the third vias 131 of the first region 100 may be disposed to have the second spacing P2. The second vias 221 of the second region 200 adjacent to each other among the second vias 221 of the second region 200, the second connection pads 222 of the second region 200 adjacent to each other among the second connection pads 222 of the second region 200, the second connection members 210 of the second region 200 adjacent to each other among the second connection members 210 of the second region 200, the fourth connection pads 232 of the second region 200 adjacent to each other among the fourth connection pads 232 of the second region 200, and the fourth vias 231 of the second region 200 adjacent to each other among the fourth vias 231 of the second region 200 may be arranged to have the first spacing P1. In some example embodiments, the second spacing P2 may be about four times the first spacing P1. In some example embodiments, the second spacing P2 may be about less than or equal to four times the first spacing P1. In some example embodiments, the second spacing P2 may be about more than twice, and about less than or equal to four times the first spacing P1.

FIG. 6 is a top plan view illustrating the arrangement of the first connection members 110 of the first region 100 and the second connection members 210 of the second region 200 in the semiconductor package 10 of FIG. 5. FIG. 6 is a top plan view illustrating the semiconductor package 10 of FIG. 5, with the upper structure 30 and the first insulating member 24 removed.

Referring to FIG. 6, the semiconductor package 10 may include the first region 100 and the second region 200. In some example embodiments, the first region 100 may include a circular shape. The first region 100 may have the center of the semiconductor package 10 (the center of the interconnect structure 40) as its center. In some example embodiments, the area of the first region 100 of the semiconductor package 10 may be about 15% of the area A of the entire region (the sum of the area of the first region 100 and the area of a second region 200) of the connection surface. In some example embodiments, the area of the first region 100 of the semiconductor package 10 may be larger or smaller than about 15% of the area A of the entire region of the connection surface. The first region 100 may have a radius extending from the center of the semiconductor package 10 (the center of the interconnect structure 40) to a desired (and/or alternatively predetermined) distance, which may be characterized as a first distance. In some example embodiments, the desired (and/or alternatively predetermined) distance of the first region 100 may be about

$$\sqrt{\frac{0.15 \times A}{π}} .$$

In some example embodiments, the desired (and/or alternatively predetermined) distance of first region 100 may be greater or less than about

$$\sqrt{\frac{0.15 \times A}{π}} .$$

The second region 200 may be defined as a region outside the first region 100.

In the first region 100, the first connection members 110 may be arranged in a staggered form. The first connection members 110 adjacent to each other among the first connection members 110 in the first region 100 may be arranged with the second spacing P2 in the first horizontal direction (direction parallel to line A-A). A fifth spacing P5 in a third horizontal direction (direction orthogonal to line A-A) of the first connection members 110 adjacent to each other among the first connection members 110 in the first region 100 may be the same as the second spacing P2 in the first horizontal direction (direction parallel to the line A-A) of the first connection members 110 adjacent to each other among the first connection members 110 in the first region 100. The staggered form is an optimized form that allows for a wide arrangement of the second spacing P2 between the first connection members 110 adjacent to each other among the first connection members 110 in the first region 100, while still allowing for the necessary amount of input/output signals to be transmitted and received for the electrical connection between the lower structure 20 and the upper structure 30.

The second spacing P2 in the first horizontal direction of the first connection members 110 of the first region 100 may be about four times the first spacing P1 in the first horizontal direction of the second connection members 210 of the second region 200. The second spacing P2 in the first horizontal direction of the first connection members 110 of the first region 100 may be about more than twice and about less than or equal to four times the first spacing P1 in the first horizontal direction of the second connection members 210 of the second region 200. The third spacing P3 (in the third horizontal direction) between the first connection members 110 at the closest distance among the first connection members 110 of the first region 100 may be about 2√2 times the first spacing P1 in the first horizontal direction of the second connection members 210 of the second region 200. The third spacing P3 (in the third horizontal direction) between the first connection members 110 at the closest distance among the first connection members 110 of the first region 100 may be about more than √2 times and about less than or equal to 2√2 times the first spacing P1 in the first horizontal direction of the second connection members 210 of the second region 200.

As a result of testing, in the embodiments of FIGS. 5 and 6, where the area of the first region 100 of the semiconductor package 10 becomes about 15% of the area of the entire region (the sum of the area of the first region 100 and the area of the second region 200) of the connection surface, the allowable value of warpage is increased by about 8 μm compared to the allowable value of warpage of the conventional art. With this, the allowable value of warpage of the semiconductor package increases, so when performing SMT, the warpage of the semiconductor package may be adjusted within the allowable value of warpage to limit and/or prevent a short from occurring between the second connection members 210.

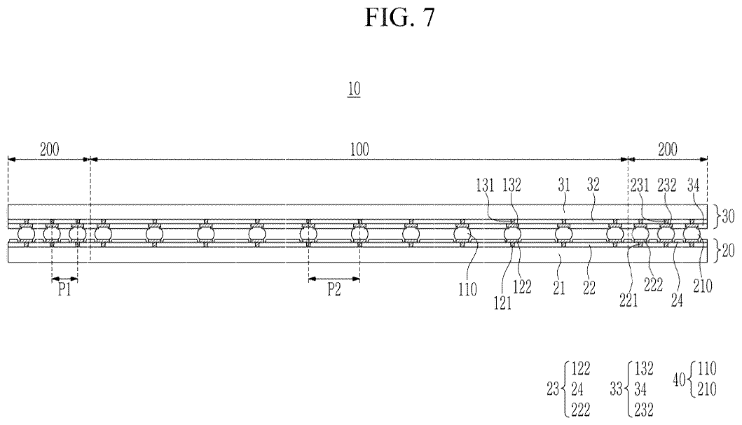

FIG. 7 is a cross-sectional view illustrating the semiconductor package 10 according to some other example embodiments of the inventive concepts.

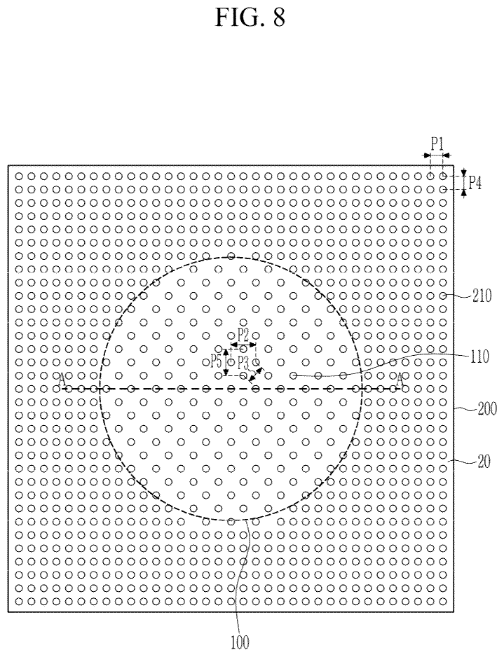

FIG. 7 is a cross-sectional view of the top plan view of the semiconductor package 10 of FIG. 8 taken along line A-A. In FIG. 7, the area of the first region 100 of the semiconductor package 10 may be about 30% of the area of the entire region of the connection surface (the sum of the area of the first region 100 and the area of the second region 200). In some example embodiments, the area of the first region 100 of the semiconductor package 10 may be about 5% to about 30% of the area of the entire region of the connection surface (the sum of the area of the first region 100 and the area of the second region 200). In some example embodiments, the area of the first region 100 of the semiconductor package 10 may be about 15% to about 30% of the area of the entire region of the connection surface (the sum of the area of the first region 100 and the area of the second region 200).

Referring to FIG. 7, the first vias 121 of the first region 100 adjacent to each other among the first vias 121 of the first region 100, the first connection pads 122 of the first region 100 adjacent to each other among the first connection pads 122 of the first region 100, the first connection members 110 of the first region 100 adjacent to each other among the first connection members 110 of the first region 100, the third connection pads 132 of the first region 100 adjacent to each other among the third connection pads 132 of the first region 100, and the third vias 131 of the first region 100 adjacent to each other among the third vias 131 of the first region 100 may be disposed to have the second spacing P2. The second vias 221 of the second region 200 adjacent to each other among the second vias 221 of the second region 200, the second connection pads 222 of the second region 200 adjacent to each other among the second connection pads 222 of the second region 200, the second connection members 210 of the second region 200 adjacent to each other among the second connection members 210 of the second region 200, the fourth connection pads 232 of the second region 200 adjacent to each other among the fourth connection pads 232 of the second region 200, and the fourth vias 231 of the second region 200 adjacent to each other among the fourth vias 231 of the second region 200 may be arranged to have the first spacing P1. In some example embodiments, the second spacing P2 may be about twice the first spacing P1. In some example embodiments, the second spacing P2 may be about more than twice than the first spacing P1. In some example embodiments, the second spacing P2 may be about more than twice, and about less than or equal to four times the first spacing P1.

FIG. 8 is a top plan view illustrating the arrangement of the first connection members 110 of the first region 100 and the second connection members 210 of the second region 200 in the semiconductor package 10 of FIG. 7. FIG. 8 is a top plan view illustrating the semiconductor package 10 of FIG. 7, with the upper structure 30 and the first insulating member 24 removed.

Referring to FIG. 8, the semiconductor package 10 may include the first region 100 and the second region 200. In some example embodiments, the first region 100 may include a circular shape. The first region 100 may have the center of the semiconductor package 10 (the center of the interconnect structure 40) as its center. In some example embodiments, the area of the first region 100 of the semiconductor package 10 may be about 30% of the area A of the entire region (the sum of the area of the first region 100 and the area of a second region 200) of the connection surface. In some example embodiments, the area of the first region 100 of the semiconductor package 10 may be larger or smaller than about 30% of the area A of the entire region of the connection surface. The first region 100 may have a radius extending from the center of the semiconductor package 10 (the center of the interconnect structure 40) to a desired (and/or alternatively predetermined) distance, which may be characterized as a first distance. In some example embodiments, the desired (and/or alternatively predetermined) distance of the first region 100 may be about

$$\sqrt{\frac{0.3 \times A}{π}} .$$

In some example embodiments, the desired (and/or alternatively predetermined) distance of first region 100 may be greater or less than about

$$\sqrt{\frac{0.3 \times A}{π}} .$$

The second region 200 may be defined as a region outside the first region 100.

In the first region 100, the first connection members 110 may be arranged in a staggered form. The first connection members 110 adjacent to each other among the first connection members 110 in the first region 100 may be arranged with the second spacing P2 in the first horizontal direction (direction parallel to line A-A). The fifth spacing P5 in the third horizontal direction (direction orthogonal to line A-A) of the first connection members 110 adjacent to each other among the first connection members 110 in the first region 100 may be the same as the second spacing P2 in the first horizontal direction (direction parallel to the line A-A) of the first connection members 110 adjacent to each other among the first connection members 110 in the first region 100.

The second spacing P2 in the first horizontal direction of the first connection members 110 of the first region 100 may be about twice the first spacing P1 in the first horizontal direction of the second connection members 210 of the second region 200. The second spacing P2 in the first horizontal direction of the first connection members 110 of the first region 100 may be about twice or more than the first spacing P1 in the first horizontal direction of the second connection members 210 of the second region 200. The third spacing P3 (in the third horizontal direction) between the first connection members 110 at the closest distance among the first connection members 110 of the first region 100 may be about √2 times the first spacing P1 in the first horizontal direction of the second connection members 210 of the second region 200. The third spacing P3 (in the third horizontal direction) between the first connection members 110 at the closest distance among the first connection members 110 of the first region 100 may be about √2 times or more than the first spacing P1 in the first horizontal direction of the second connection members 210 of the second region 200.

As a result of testing, in the embodiments of FIGS. 7 and 8, where the area of the first region 100 of the semiconductor package 10 becomes about 30% of the area of the entire region (the sum of the area of the first region 100 and the area of the second region 200) of the connection surface, the allowable value of warpage is increased by about 33 μm compared to the allowable value of warpage of the conventional art. With this, the allowable value of warpage of the semiconductor package increases, so when performing SMT, the warpage of the semiconductor package may be adjusted within the allowable value of warpage to limit and/or prevent a short from occurring between the second connection members 210.

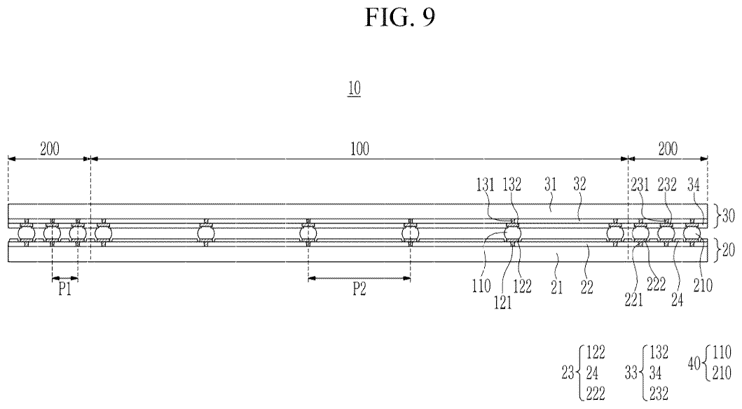

FIG. 9 is a cross-sectional view illustrating the semiconductor package 10 according to some other example embodiments of the inventive concepts.

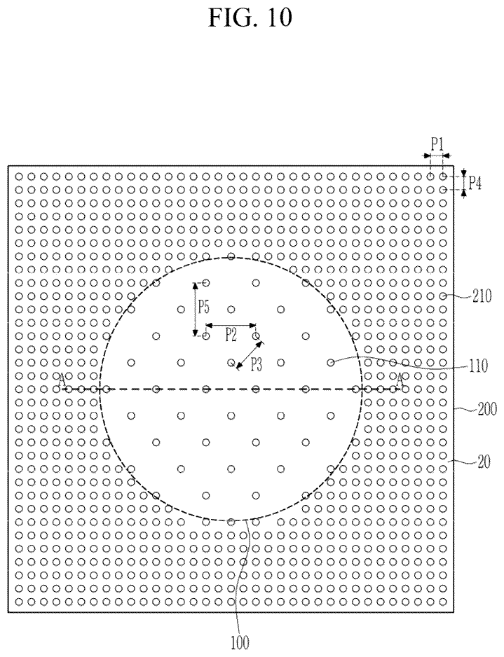

FIG. 9 is a cross-sectional view of the top plan view of the semiconductor package 10 of FIG. 10 taken along line A-A. In FIG. 9, the area of the first region 100 of the semiconductor package 10 may be about 30% of the area of the entire region of the connection surface (the sum of the area of the first region 100 and the area of the second region 200). In some example embodiments, the area of the first region 100 of the semiconductor package 10 may be about 5% to about 30% of the area of the entire region of the connection surface (the sum of the area of the first region 100 and the area of the second region 200). In some example embodiments, the area of the first region 100 of the semiconductor package 10 may be about 15% to about 30% of the area of the entire region of the connection surface (the sum of the area of the first region 100 and the area of the second region 200).

Referring to FIG. 9, the first vias 121 of the first region 100 adjacent to each other among the first vias 121 of the first region 100, the first connection pads 122 of the first region 100 adjacent to each other among the first connection pads 122 of the first region 100, the first connection members 110 of the first region 100 adjacent to each other among the first connection members 110 of the first region 100, the third connection pads 132 of the first region 100 adjacent to each other among the third connection pads 132 of the first region 100, and the third vias 131 of the first region 100 adjacent to each other among the third vias 131 of the first region 100 may be disposed to have the second spacing P2. The second vias 221 of the second region 200 adjacent to each other among the second vias 221 of the second region 200, the second connection pads 222 of the second region 200 adjacent to each other among the second connection pads 222 of the second region 200, the second connection members 210 of the second region 200 adjacent to each other among the second connection members 210 of the second region 200, the fourth connection pads 232 of the second region 200 adjacent to each other among the fourth connection pads 232 of the second region 200, and the fourth vias 231 of the second region 200 adjacent to each other among the fourth vias 231 of the second region 200 may be arranged to have the first spacing P1. In some example embodiments, the second spacing P2 may be about four times the first spacing P1. In some example embodiments, the second spacing P2 may be about less than or equal to four times the first spacing P1. In some example embodiments, the second spacing P2 may be about more than twice, and about less than or equal to four times the first spacing P1.

FIG. 10 is a top plan view illustrating the arrangement of the first connection members 110 of the first region 100 and the second connection members 210 of the second region 200 in the semiconductor package 10 of FIG. 9. FIG. 10 is a top plan view illustrating the semiconductor package 10 of FIG. 9, with the upper structure 30 and the first insulating member 24 removed.

Referring to FIG. 10, the semiconductor package 10 may include the first region 100 and the second region 200. In some example embodiments, the first region 100 may include a circular shape. The first region 100 may have the center of the semiconductor package 10 (the center of the interconnect structure 40) as its center. In some example embodiments, the area of the first region 100 of the semiconductor package 10 may be about 30% of the area A of the entire region (the sum of the area of the first region 100 and the area of a second region 200) of the connection surface. In some example embodiments, the area of the first region 100 of the semiconductor package 10 may be larger or smaller than about 30% of the area A of the entire region of the connection surface. The first region 100 may have a radius extending from the center of the semiconductor package 10 (the center of the interconnect structure 40) to a desired (and/or alternatively predetermined) distance, which may be characterized as a first distance. In some example embodiments, the desired (and/or alternatively predetermined) distance of the first region 100 may be about

$$\sqrt{\frac{0.3 \times A}{π}} .$$

In some example embodiments, the desired (and/or alternatively predetermined) distance of first region 100 may be greater or less than about

$$\sqrt{\frac{0.3 \times A}{π}} .$$

The second region 200 may be defined as a region outside the first region 100.

In the first region 100, the first connection members 110 may be arranged in a staggered form. The first connection members 110 adjacent to each other among the first connection members 110 in the first region 100 may be arranged with the second spacing P2 in the first horizontal direction (direction parallel to line A-A). The fifth spacing P5 in the third horizontal direction (direction orthogonal to line A-A) of the first connection members 110 adjacent to each other among the first connection members 110 in the first region 100 may be the same as the second spacing P2 in the first horizontal direction (direction parallel to the line A-A) of the first connection members 110 adjacent to each other among the first connection members 110 in the first region 100.

The second spacing P2 in the first horizontal direction of the first connection members 110 of the first region 100 may be about four times the first spacing P1 in the first horizontal direction of the second connection members 210 of the second region 200. The second spacing P2 in the first horizontal direction of the first connection members 110 of the first region 100 may be about more than twice and about less than or equal to four times the first spacing P1 in the first horizontal direction of the second connection members 210 of the second region 200. The third spacing P3 (in the third horizontal direction) between the first connection members 110 at the closest distance among the first connection members 110 of the first region 100 may be about 2√2 times the first spacing P1 in the first horizontal direction of the second connection members 210 of the second region 200. The third spacing P3 (in the third horizontal direction) between the first connection members 110 at the closest distance among the first connection members 110 of the first region 100 may be about less than or equal to 2√2 times the first spacing P1 in the first horizontal direction of the second connection members 210 of the second region 200. The third spacing P3 (in the third horizontal direction) between the first connection members 110 at the closest distance among the first connection members 110 of the first region 100 may be about more than √2 times and about less than or equal to 2√2 times the first spacing P1 in the first horizontal direction of the second connection members 210 of the second region 200.

As a result of testing, in the embodiments of FIGS. 9 and 10, where the area of the first region 100 of the semiconductor package 10 becomes about 30% of the area of the entire region (the sum of the area of the first region 100 and the area of the second region 200) of the connection surface, the allowable value of warpage is increased by about 33 μm compared to the allowable value of warpage of the conventional art. With this, the allowable value of warpage of the semiconductor package increases, so when performing SMT, the warpage of the semiconductor package may be adjusted within the allowable value of warpage to limit and/or prevent a short from occurring between the second connection members 210.

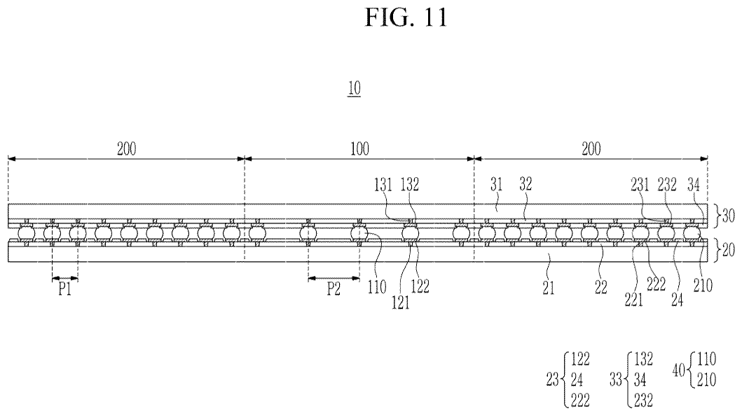

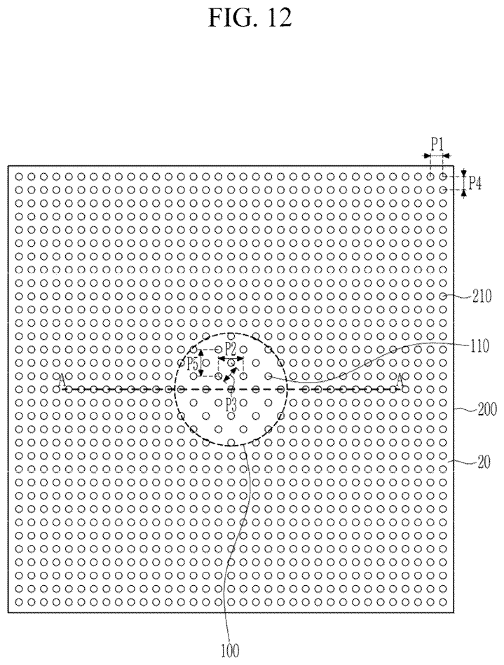

FIG. 11 is a cross-sectional view illustrating the semiconductor package 10 according to some other example embodiments of the inventive concepts. FIG. 11 is a cross-sectional view of the top plan view of the semiconductor package 10 of FIG. 12 taken along line A-A. In FIG. 11, the area of the first region 100 of the semiconductor package 10 may be about 5% of the area of the entire region (the sum of the area of the first region 100 and the area of a second region 200) of the connection surface. In some example embodiments, the area of the first region 100 of the semiconductor package 10 may be about 5% to about 15% of the area of the entire region of the connection surface (the sum of the area of the first region 100 and the area of the second region 200). In some example embodiments, the area of the first region 100 of the semiconductor package 10 may be about 5% to about 30% of the area of the entire region of the connection surface (the sum of the area of the first region 100 and the area of the second region 200).

Referring to FIG. 11, the first vias 121 of the first region 100 adjacent to each other among the first vias 121 of the first region 100, the first connection pads 122 of the first region 100 adjacent to each other among the first connection pads 122 of the first region 100, the first connection members 110 of the first region 100 adjacent to each other among the first connection members 110 of the first region 100, the third connection pads 132 of the first region 100 adjacent to each other among the third connection pads 132 of the first region 100, and the third vias 131 of the first region 100 adjacent to each other among the third vias 131 of the first region 100 may be disposed to have the second spacing P2. The second vias 221 of the second region 200 adjacent to each other among the second vias 221 of the second region 200, the second connection pads 222 of the second region 200 adjacent to each other among the second connection pads 222 of the second region 200, the second connection members 210 of the second region 200 adjacent to each other among the second connection members 210 of the second region 200, the fourth connection pads 232 of the second region 200 adjacent to each other among the fourth connection pads 232 of the second region 200, and the fourth vias 231 of the second region 200 adjacent to each other among the fourth vias 231 of the second region 200 may be arranged to have the first spacing P1. In some example embodiments, the second spacing P2 may be about twice the first spacing P1. In some example embodiments, the second spacing P2 may be about more than twice than the first spacing P1. In some example embodiments, the second spacing P2 may be about more than twice, and less than or equal to four times the first spacing P1.

FIG. 12 is a top plan view illustrating the arrangement of the first connection members 110 of the first region 100 and the second connection members 210 of the second region 200 in the semiconductor package 10 of FIG. 11. FIG. 12 is a top plan view illustrating the semiconductor package 10 of FIG. 11, with the upper structure 30 and the first insulating member 24 removed.

Referring to FIG. 12, the semiconductor package 10 may include the first region 100 and the second region 200. In some example embodiments, the first region 100 may include a circular shape. The first region 100 may have the center of the semiconductor package 10 (the center of the interconnect structure 40) as its center. In some example embodiments, the area of the first region 100 of the semiconductor package 10 may be about 5% of the area A of the entire region (the sum of the area of the first region 100 and the area of a second region 200) of the connection surface. In some example embodiments, the area of the first region 100 of the semiconductor package 10 may be larger or smaller than about 5% of the area A of the entire region of the connection surface. The first region 100 may have a radius extending from the center of the semiconductor package 10 (the center of the interconnect structure 40) to a desired (and/or alternatively predetermined) distance, which may be characterized as a first distance. In some example embodiments, the desired (and/or alternatively predetermined) distance of the first region 100 may be about

$$\sqrt{\frac{0.05 \times A}{π}} .$$

In some example embodiments, the desired (and/or alternatively predetermined) distance of first region 100 may be greater or less than about

$$\sqrt{\frac{0.05 \times A}{π}} .$$

The second region 200 may be defined as a region outside the first region 100.

In the first region 100, the first connection members 110 may be arranged in a staggered form. The first connection members 110 adjacent to each other among the first connection members 110 in the first region 100 may be arranged with the second spacing P2 in the first horizontal direction (direction parallel to line A-A). The fifth spacing P5 in the third horizontal direction (direction orthogonal to line A-A) of the first connection members 110 adjacent to each other among the first connection members 110 in the first region 100 may be the same as the second spacing P2 in the first horizontal direction (direction parallel to the line A-A) of the first connection members 110 adjacent to each other among the first connection members 110 in the first region 100.

The second spacing P2 in the first horizontal direction of the first connection members 110 of the first region 100 may be about twice the first spacing P1 in the first horizontal direction of the second connection members 210 of the second region 200. The second spacing P2 in the first horizontal direction of the first connection members 110 of the first region 100 may be more than twice the first spacing P1 in the first horizontal direction of the second connection members 210 of the second region 200. The third spacing P3 (in the third horizontal direction) between the first connection members 110 at the closest distance among the first connection members 110 of the first region 100 may be about √2 times the first spacing P1 in the first horizontal direction of the second connection members 210 of the second region 200. The third spacing P3 (in the third horizontal direction) between the first connection members 110 at the closest distance among the first connection members 110 of the first region 100 may be about more than √2 times the first spacing P1 in the first horizontal direction of the second connection members 210 of the second region 200. The third spacing P3 (in the third horizontal direction) between the first connection members 110 at the closest distance among the first connection members 110 of the first region 100 may be about more than √2 times and less than or equal to 2√2 times the first spacing P1 in the first horizontal direction of the second connection members 210 of the second region 200.

As a result of testing, in FIGS. 11 and 12, where the area of the first region 100 of the semiconductor package 10 becomes about 5% of the area of the entire region (the sum of the area of the first region 100 and the area of the second region 200) of the connection surface, the allowable value of warpage is increased by about 1 μm compared to the allowable value of warpage of the conventional art. With this, the allowable value of warpage of the semiconductor package increases, so when performing SMT, the warpage of the semiconductor package may be adjusted within the allowable value of warpage to limit and/or prevent a short from occurring between the second connection members 210.

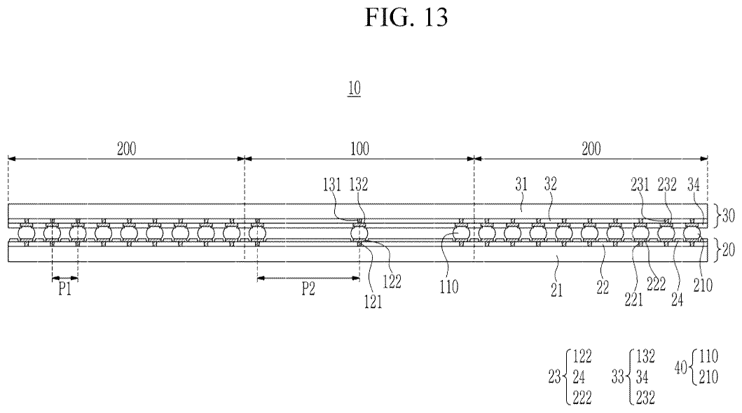

FIG. 13 is a cross-sectional view illustrating a semiconductor package according to some other example embodiments of the inventive concepts.

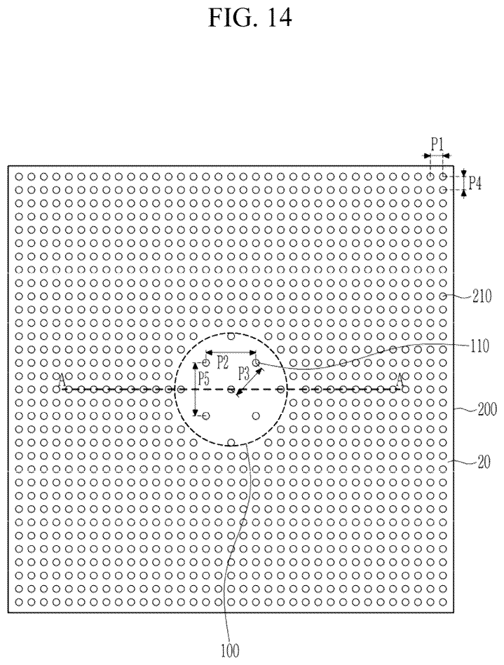

FIG. 13 is a cross-sectional view of the top plan view of the semiconductor package 10 of FIG. 14 taken along line A-A. In FIG. 13, the area of the first region 100 of the semiconductor package 10 may be about 5% of the area of the entire region (the sum of the area of the first region 100 and the area of a second region 200) of the connection surface. In some example embodiments, the area of the first region 100 of the semiconductor package 10 may be about 5% to about 15% of the area of the entire region of the connection surface (the sum of the area of the first region 100 and the area of the second region 200). In some example embodiments, the area of the first region 100 of the semiconductor package 10 may be about 5% to about 30% of the area of the entire region of the connection surface (the sum of the area of the first region 100 and the area of the second region 200).

Referring to FIG. 13, the first vias 121 of the first region 100 adjacent to each other among the first vias 121 of the first region 100, the first connection pads 122 of the first region 100 adjacent to each other among the first connection pads 122 of the first region 100, the first connection members 110 of the first region 100 adjacent to each other among the first connection members 110 of the first region 100, the third connection pads 132 of the first region 100 adjacent to each other among the third connection pads 132 of the first region 100, and the third vias 131 of the first region 100 adjacent to each other among the third vias 131 of the first region 100 may be disposed to have the second spacing P2. The second vias 221 of the second region 200 adjacent to each other among the second vias 221 of the second region 200, the second connection pads 222 of the second region 200 adjacent to each other among the second connection pads 222 of the second region 200, the second connection members 210 of the second region 200 adjacent to each other among the second connection members 210 of the second region 200, the fourth connection pads 232 of the second region 200 adjacent to each other among the fourth connection pads 232 of the second region 200, and the fourth vias 231 of the second region 200 adjacent to each other among the fourth vias 231 of the second region 200 may be arranged to have the first spacing P1. In some example embodiments, the second spacing P2 may be about four times the first spacing P1. In some example embodiments, the second spacing P2 may be about more than twice, and about less than or equal to four times the first spacing P1.

FIG. 14 is a top plan view illustrating the arrangement of the first connection members 110 of the first region 100 and the second connection members 210 of the second region 200 in the semiconductor package 10 of FIG. 13. FIG. 14 is a top plan view illustrating the semiconductor package 10 of FIG. 13, with the upper structure 30 and the first insulating member 24 removed.

Referring to FIG. 14, the semiconductor package 10 may include the first region 100 and the second region 200. In some example embodiments, the first region 100 may include a circular shape. The first region 100 may have the center of the semiconductor package 10 (the center of the interconnect structure 40) as its center. In some example embodiments, the area of the first region 100 of the semiconductor package 10 may be about 5% of the area A of the entire region (the sum of the area of the first region 100 and the area of a second region 200) of the connection surface. In some example embodiments, the area of the first region 100 of the semiconductor package 10 may be larger or smaller than about 5% of the area A of the entire region of the connection surface. The first region 100 may have a radius extending from the center of the semiconductor package 10 (the center of the interconnect structure 40) to a desired (and/or alternatively predetermined) distance, which may be characterized as a first distance. In some example embodiments, the desired (and/or alternatively predetermined) distance of the first region 100 may be about

$$\sqrt{\frac{0.05 \times A}{π}} .$$

In some example embodiments, the desired (and/or alternatively predetermined) distance of first region 100 may be greater or less than about

$$\sqrt{\frac{0.05 \times A}{π}} .$$

The second region 200 may be defined as a region outside the first region 100.

In the first region 100, the first connection members 110 may be arranged in a staggered form. The first connection members 110 adjacent to each other among the first connection members 110 in the first region 100 may be arranged with the second spacing P2 in the first horizontal direction (direction parallel to line A-A). The fifth spacing P5 in the third horizontal direction (direction orthogonal to line A-A) of the first connection members 110 adjacent to each other among the first connection members 110 in the first region 100 may be the same as the second spacing P2 in the first horizontal direction (direction parallel to the line A-A) of the first connection members 110 adjacent to each other among the first connection members 110 in the first region 100.

The second spacing P2 in the first horizontal direction of the first connection members 110 of the first region 100 may be about four times the first spacing P1 in the first horizontal direction of the second connection members 210 of the second region 200. The second spacing P2 in the first horizontal direction of the first connection members 110 of the first region 100 may be about more than twice and about less than or equal to four times the first spacing P1 in the first horizontal direction of the second connection members 210 of the second region 200. The third spacing P3 (in the third horizontal direction) between the first connection members 110 may be about 2√2 times the first spacing P1 in the first horizontal direction of the second connection members 210 of the second region 200. The third spacing P3 (in the third horizontal direction) between the first connection members 110 at the closest distance among the first connection members 110 of the first region 100 may be about less than or equal to 2√2 times the first spacing P1 in the first horizontal direction of the second connection members 210 of the second region 200. The third spacing P3 (in the third horizontal direction) between the first connection members 110 at the closest distance among the first connection members 110 of the first region 100 may be about more than √2 times and about less than or equal to 2√2 times the first spacing P1 in the first horizontal direction of the second connection members 210 of the second region 200.

As a result of testing, in FIGS. 13 and 14, where the area of the first region 100 of the semiconductor package 10 becomes about 5% of the area of the entire region (the sum of the area of the first region 100 and the area of the second region 200) of the connection surface, the allowable value of warpage is increased by about 1 μm compared to the allowable value of warpage of the conventional art. With this, the allowable value of warpage of the semiconductor package increases, so when performing SMT, the warpage of the semiconductor package may be adjusted within the allowable value of warpage to limit and/or prevent a short from occurring between the second connection members 210.

While the inventive concepts have been described in connection with what is presently considered to be practical example embodiments, it is to be understood that the inventive concepts are not limited to the disclosed example embodiments, but, on the contrary, are intended to cover various modifications and equivalent arrangements included within the spirit and scope of the appended claims.

What is claimed is:

1. A semiconductor package, comprising:
a first structure;
a second structure; and
an interconnect structure between the first structure and the second structure,
wherein the interconnect structure comprises
a first region extending from a center of the interconnect structure to a first distance,
a second region outside the first region, and
a plurality of first connection members in the first region and a plurality of second connection members in the second region,
the plurality of first connection members are arranged in a staggered form, and
the plurality of second connection members are arranged in a row.

2. The semiconductor package of claim 1, comprising
a fine pitch ball grid array (FBGA) package.

3. The semiconductor package of claim 1, wherein
the first region has a circular shape.

4. The semiconductor package of claim 1, wherein
second connection members of the plurality of second connection members that are closest to each other are arranged at a first spacing in a first horizontal direction,
the plurality of first connection members are arranged at a second spacing in the first horizontal direction,
the second spacing is twice to four times the first spacing.

5. The semiconductor package of claim 4, wherein
first connection members of the plurality of first connection members that are closest to each other are arranged at a third spacing in a second horizontal direction,
the third spacing is √2 times to 2√2 times the first spacing.

6. The semiconductor package of claim 4, wherein
the plurality of second connection members are arranged at a fourth spacing in a third horizontal direction orthogonal to the first horizontal direction,
the fourth spacing and the first spacing are the same.

7. The semiconductor package of claim 1, wherein
an area of the first region is 5% to 15% of an entire area of the interconnect structure.

8. The semiconductor package of claim 1, wherein
an area of the first region is 15% to 30% of an entire area of the interconnect structure.

9. The semiconductor package of claim 1, wherein
an area of the first region is 5% to 30% of an entire area of the interconnect structure.

10. A semiconductor structure, comprising:
a die base; and
a connection structure on a surface of the die base,
wherein the connection structure comprises
a first region extending from a center of the connection structure to a first distance,
a second region outside the first region,
an insulating member including a plurality of through openings,
a plurality of first connection pads in the first region, and
a plurality of second connection pads in the second region,
the plurality of first connection pads and the plurality of second connection pads are within respective ones of the plurality of through openings,
the plurality of first connection pads are arranged in a staggered form, and
the plurality of second connection pads are arranged in a row.

11. The semiconductor structure of claim 10, wherein
the insulating member includes solder resist.

12. The semiconductor structure of claim 10, wherein the die base and the connection structure configure
an interposer, a semiconductor chip, a three dimensional integrated circuit structure, a bridge die, a passive device, or a substrate.

13. A semiconductor package, comprising:
a substrate including a first die base, a plurality of first connection pads on an upper surface of the first die base, and a plurality of second connection pads on the upper surface of the first die base;
a semiconductor structure including a second die base, a plurality of third connection pads on a lower surface of the second die base, and a plurality of fourth connection pads on the lower surface of the second die base; and
an interconnect structure between the substrate and the semiconductor structure,
wherein the interconnect structure comprises
a first region extending from a center of the interconnect structure to a first distance,
a second region outside the first region, and
a plurality of first connection members in the first region and a plurality of second connection members in the second region,
the plurality of first connection members are arranged in a staggered form, and
the plurality of second connection members are arranged in a row.

14. The semiconductor package of claim 13, wherein
the plurality of first connection members are between the plurality of first connection pads and the plurality of third connection pads.

15. The semiconductor package of claim 13, wherein
the plurality of second connection members are between the plurality of second connection pads and the plurality of fourth connection pads.

16. The semiconductor package of claim 13, wherein
the substrate comprises a printed circuit board.

17. The semiconductor package of claim 13, wherein
the semiconductor structure comprises a system on chip.

18. The semiconductor package of claim 13, wherein
the plurality of first connection members are electrically connected to at least one of a communication chip and a sensor.

19. The semiconductor package of claim 13, wherein
the plurality of second connection members are electrically connected to at least one of a neural processing unit, a central processing unit, and a graphic processing unit.

20. The semiconductor package of claim 13, wherein
the plurality of first connection pads and the plurality of third connection pads are arranged in the staggered form,
the plurality of second connection pads and the plurality of fourth connection pads are arranged in the row.
